(19) United States
(12) Patent Application Publication
(10) Pub. No.: US 2003/0040196 A1
(43) Pub. Date: Feb. 27, 2003

(54) Method of forming insulation layer in semiconductor devices for controlling the composition and the doping concentration

(76) Inventors: Jung Wook Lim, Daejon-Shi (KR); Young Joo Song, Suwon-Shi (KR); Kyu Hwan Shim, Daejon-Shi (KR); Jin Yeong Kang, Daejon-Shi (KR)

Correspondence Address: JACOBSON, PRICE, HOLMAN & STERN, PROFESSIONAL LIMITED LIABILITY COMPANY, 400 Seventh Street, N.W., Washington, DC, 20004, US

(21) Appl. No.: 09/984,233

(22) Filed: Oct. 29, 2001

(30) Foreign Application Priority Data
Aug. 27, 2001 (KR) 2001-51703

(51) Int. Cl. H01L 21/469; H01L 21/31

(52) U.S. Cl. 438/785; 438/786; 438/787; 438/790

(57) ABSTRACT

The present invention relates to a method of forming an insulating film in a semiconductor device by which the composition and the doping concentration of oxide are controlled using an atomic layer deposition method. In case of silicon oxide, a thermal oxidization process and a deposition process are sequentially performed to form an oxide film having a good interface characteristic and the deposition speed. On the other hand, in case of depositing an oxide film, an oxynitride film and a metal oxide film, the pulse construction and the supply time of a source and radical are adjusted to form an optimum oxide film having a good interface characteristic.

### BACKGROUND OF THE INVENTION

1. Field of the Invention

The present invention relates generally to a method of forming an insulating film in a semiconductor device. More particularly, the present invention relates to a method of forming an insulating film in a semiconductor device capable of improving an interface characteristic and controlling the composition ratio using an atomic layer deposition method or a chemical vapor deposition method.

2. Description of the Prior Art

Recently, the manufacture technology of semiconductor devices has been remarkably improved. In particular, as high performance microprocessor and wireless communication markets are expanded, the manufacture technology of CMOS devices becomes further important.

In the process of manufacturing a MOS transistor made of a metal, oxide and silicon (Si), a gate dielectric film is mostly formed of oxide or oxynitride. The operating characteristic of the device depends on the characteristic of the gate dielectric film. In other words, if the interface characteristic and the film quality of the gate dielectric film are improved, the operating characteristic of the device can be improved. Therefore, there is a need for an improvement of a process technology for forming an oxide film and an oxynitride film.

The oxide film is used to manufacture not only a CMOS device but also a memory device. The oxide film used for the dielectric film of the memory device must have a different characteristic from the oxide film used for the gate dielectric film of the CMOS device.

The oxide film used for the gate dielectric film must have a good adaptability with silicon (Si) being an underlying layer and have a good interface stability with silicon (Si). On the other hand, the oxide film used as the dielectric film in the memory device has good characteristics such as a leakage current, a dielectric constant, etc. but the interface characteristic of the oxide film with an underlying electrode are less considered. Therefore, there is a need for an oxide deposition system that can be further easily applied variations in the process parameter and selection of the material.

Generally, the gate oxide film is mainly formed of amorphous silicon oxide that is thermally grown. This thermal oxide film has a good interface characteristic, less leakage current and a low density of defective charges. It is usually required that the gate oxide film have the defective charge density of about 10¹⁰/cm²eV.

As the semiconductor devices are higher integrated, there is a trend that the equivalent thickness of the oxide film is reduced from 20 Å to below 10 Å.

According to a theoretical research by Tang, et al., the minimum equivalent thickness of oxide at which the oxide can maintain the bulk characteristic is 7 Å. If the equivalent thickness is below it, the oxide does not function as an insulator by shortage. However, though the equivalent thickness of the oxide film is thick, there is a limit that the equivalent thickness of the oxide film is reduced since the tunneling current is increased in equivalent thickness of below 20 Å.

In order to solve these problems, there was proposed a method of growing oxynitride instead of oxide to reduce the tunneling current effect even in a thin thickness so that the leakage current characteristic can be improved. It was reported that the dielectric constant (κ) of pure silicon nitride (Si₃N₄) is about 7 and oxynitride prevents penetration of boron(B) (see Y. Wu et al., IEEE Electron Device Letter, 19, p 367).

However, it was reported that it would be very effective to add a little amount of nitrogen (N) but if a large quantity of nitrogen (N) is added, the characteristic of the device is degraded due to excessive charges by 5 valence nitrogen atoms and defects in the interface.

In view of the above, there is a need for a technology of adding a little nitrogen (N) and easily controlling the composition of nitrogen (K. A. Ellis et al., Applied Physics Letter, 74, p 967).

In order to deposit oxide having more a greater dielectric constant, control of a fine composition is required. However, as there is a limit that oxynitride reduce the equivalent thickness of silicon oxide, there has been a research into a metal oxide having a great dielectric constant as a substitution oxide.

There was a research to oxidize Ta, Ti, etc. to produce a metal oxide. If this metal oxide is used, however, the characteristic of the device is degraded as a silicon oxide is generated due to the interface reaction with silicon. Therefore, there is a need for development of a metal oxide that is thermodynamically stable.

According to recent prior arts, it was reported that the crystallization temperature can be increased, the amorphous state can be maintained and generation of SiO₂ can be mitigated by growing oxide such as Ta₁₋ₓAlO_{y} or Ta₁₋ₓSiₓO_{y} TaOₓ in which a small amount of silicon (Si) or aluminum (Al) is added, so that a good characteristic and the surface shape could be obtained (Glen B. Alers et al., U.S. Pat. No. 6,060,406A). In order to control of such fine composition, it is considered that an atomic layer deposition (ALD) is most suitable.

In case of aluminum (Al), it was reported that the stability is maintained but the dielectric constant is not so high, so that boron (B) can be diffused in a subsequent process. In addition, as deposition of aluminum is performed in a thermodynamically unstable state, silicate can be generated to degrade the characteristic of the device. However, if a thin film is grown with the atomic layer being controlled, a thin film that is thermally stable can be grown and generation of silicate can be also prevented. Actually, there was a report that generation of silicate is prohibited in case of the atomic layer chemical deposition method. Therefore, if the ALD method is used, the stability of the interface can be maintained.

For the purpose of the interface stability of oxides used for this gate oxide film, there has recently been a study on oxide of lanthanum group atoms such as Hf, Zr, Y, La, Pr, Nd, Dy, Gd, etc. There was reported that general characteristics having an interface characteristic with silicon are good. In case of Zr, ZrO₂, ZrSiO₄, etc. maintains with a stable state even it contacts silicon. It was reported that the specific inductive capacity of ZrO₂ is 25 but the specific inductive capacity of ZrSiO₄ is 12.6. However, ZrO₂ is crystallized and becomes ion-conductive at low temperature. The channel mobility of electrons is reduced due to a hetero interface with silicon. In case of ZrSiO₄, though the crystallization temperature is high, there is a disadvantage that a deposition material of ZrO₂ can be generated.

According to a recent article, in case that silicon oxide is grown by adding a small amount of Zr of 3-5% in the shape of ZrSiₓO_{y}, a good oxide film having a low leakage current and having an amorphous state can be obtained (G. D. Wilk et al., Journal of Applied Physics, 87, p 484).

A similar result was obtained from HfSiₓO_{y} as well as ZrSiₓO_{y}. However, this silicon (Si)-rich metal oxide is deposited by means of a sputtering method. This method has disadvantages that it is difficult to control the composition of silicon and metal, and must use a target the composition of which is first set. Therefore, if the ALD method is employed, it would be helpful to find an optimum composition having a good characteristic since the change of the composition can be easily controlled. Also, in case of amorphous, Gd₂O₃, Y₂O₃, etc. have a low leakage current and prohibit an interface reaction with silicon. Also, Gd₂O₃, Y₂O₃, etc. have a good uniformity of a thin film and a flat surface shape can be obtained from them. If Gd₂O₃, Y₂O₃, etc. are grown in a crystal shape, they have a higher leakage current than amorphous and its surface shape is bad. Also, it was reported that the heating rate is high and a SiO₂ layer can be formed under oxygen atmosphere at high temperature. Therefore, it is preferred that a subsequent process is performed under an inactive gas atmosphere and Gd₂O₃, Y₂O₃, etc. is maintained in an amorphous shape.

In addition, it was reported that though the oxides of a lanthanum series have a good interface stability but the flat voltage is moved by about −1.4V since positive charges exist within a thin film.

There was a report that in a prior art the characteristic of oxide is improved by adding the dopant, the characteristic can be improved by reducing defects in the interface such as an unwanted strained bond by doping IV-group materials into III-group and VB-group oxides. It is preferred that the doping concentration can be controlled from 0.1% to 10%. It would be advantageous that the composition is controlled using the ALD method (W. H. Lee et al., U.S. Pat. No. 923,056A).

As such, in order to grow an optimum oxide having a good characteristic while having the interface stability with silicon, SiₓM₁₋ₓO_{y} oxide in which silicon and metal are mixed and M₁ₓM₂₍₁₋ₓ₎O_{y} oxide in which metal (M₁) and metal (M₂) are mixed are usually employed. As there is a report that the crystallization temperature can be increased or the interface can be improved by adding silicon and 4-group elements, there is a need for a new deposition method by which the composition can be finely controlled.

### SUMMARY OF THE INVENTION

It is therefore an object of the present invention to provide a method of forming an insulating film in a semiconductor device capable of solving the above problems by controlling the pulse construction and the supply time of source and radicals in the deposition process using an atomic layer deposition (ALD) method.

Another object of the present invention is to provide a method of growing an oxide film for a gate or a dielectric film in a memory device by variously controlling the composition, the doping concentration and the thickness of a thin film in a silicon oxide, silicon oxynitride, a metal oxide having a high dielectric constant or oxides made of these compounds and a doping oxide using the ALD method.

In order to accomplish the above object, a method of forming an insulating film in a semiconductor device according to the present invention is characterized in that it comprises the step of alternately performing a silicon source injection process and an oxidization reaction gas injection process to form a deposition oxide film on a silicon substrate, wherein the oxidization reaction gas employs oxygen radical or ozone.

A method of forming an insulating film in a semiconductor device according to the present invention is characterized in that it comprises the step of forming a silicon oxynitride film using a silicon organic precursor, an oxygen precursor and a nitrogen precursor, wherein the oxygen precursor employs an oxygen radical, and the nitrogen precursor employs one of a nitrogen radical, ammonium and N₂O.

A method of forming an insulating film in a semiconductor device according to the present invention is characterized in that it comprises the step of alternately performing a metal precursor injection process and a hydrogen radical injection process and then performing an annealing process under oxygen radical or ozone atmosphere to form a metal thermal oxide film.

A method of forming an insulating film in a semiconductor device according to the present invention is characterized in that it comprises the step of alternately performing a metal precursor injection process, an oxygen radical injection process, a dopant precursor injection process and a hydrogen radical injection process to form a metal oxide film.

A silicon thermal oxide film has been used the oxide film for a gate so far, which is grown at a high temperature of over 800° C. In case of manufacturing a high speed MOSFET device the channel of which is made of SiGe, however, as the temperature in a subsequent process must be lower to below 800° C., it is required that the oxide film be grown at low temperature. In order to implement it, a thermal oxide film is formed at low temperature using ozone or oxygen radicals or SiO₂ is deposited using a silicon (Si) precursor and a reaction gas.

Generally speaking, the interface characteristic of the deposition material is less than the thermal oxide film but is rapid in the deposition speed. Therefore, the thermal oxide film is formed at the interface with the silicon substrate using these advantages and a deposition oxide film is formed thereon to implement a thin SiO₂ film. In this case, the ALD method may be employed.

Also, the leakage current can be reduced and the penetration of boron (B) can be prohibited, by adding nitrogen (N) to form a thin film of a Si-O-N shape. As a result, the characteristic improvement effect can be obtained by adding nitrogen (N) during the ALD process.

As the channel length is reduced depending on higher integrated devices, if an oxide film such as SiO₂ or SiON is employed, the leakage current can be increased. Therefore, it is required that a metal oxide of a high dielectric constant be instead used.

Materials that will be used as a next-generation oxide film for a gate include Ti, Ta, etc. A study on these oxides has been made. There was a report that SiO₂ is generated at the interface to reduce the capacitance if these oxides are employed. However, it was also reported that if silicon (Si) and aluminum (Al) are added, the crystallization temperature is increased and generation of SiO₂ is delayed.

For the purpose of the interface stability with silicon (Si), a study has been made on metal oxides of Y, Zr, Hf and lanthanum groups. It was reported that the characteristic can be improved by doping 4-group metal and silicon (Si) to 3-group and 5 group oxides.

Further, as oxides of Zr or Hf itself have a low crystallization temperature, there was a report that it would be effective to add silicon (Si) in a SiₓZr₁₋ₓO_{y} or SiₓHf₁₋ₓO_{y} shape in order to maintain it in an amorphous shape.

Therefore, in the prevent invention, oxides are deposited by means of an atomic layer deposition method using organic source and oxygen radicals to effectively control the composition and the doping concentration.

### BRIEF DESCRIPTION OF THE DRAWINGS

The aforementioned aspects and other features of the present invention will be explained in the following description, taken in conjunction with the accompanying drawings, wherein:

FIG. 1a is a cross-sectional view of a semiconductor device for explaining a method of forming an oxide film made of a thermal oxide film and a deposition oxide film;

FIG. 1b is a process flow for explaining FIG. 1a;

FIGS. 2a through 2d are process flows for explaining a method of forming a silicon oxynitride film according to one embodiment of the present invention;

FIG. 3a, FIG. 3b and FIG. 3e are process flows for explaining a method of forming a metal oxide film having a high dielectric constant according to one embodiment of the present invention;

FIG. 3c is a cross-sectional view of the device for explaining FIG. 3e;

FIG. 3d is a graph for explaining FIG. 3e;

FIG. 4a and FIG. 4b are cross-sectional views of the device for explaining a method of forming a metal thermal oxide film according to another embodiment of the present invention;

FIG. 4c is a process flow for explaining FIG. 4a and FIG. 4b;

FIG. 5a and FIG. 5c are cross-sectional views for explaining a method of forming a metal oxide film made of an oxidized mixture of a metal (M₁) and another metal (M₂);

FIG. 5b and FIG. 5d are process flows for explaining FIG. 5a and FIG. 5c;

FIG. 6 is a process flow for explaining a metal oxide film for which doping is performed; and

FIG. 7 is a construction of a deposition apparatus used to deposit oxide on a semiconductor substrate using an atomic layer deposition method.

### DETAILED DESCRIPTION OF PREFERRED EMBODIMENTS

The present invention will be described in detail by way of a preferred embodiment with reference to accompanying drawings, in which like reference numerals are used to identify the same or similar parts.

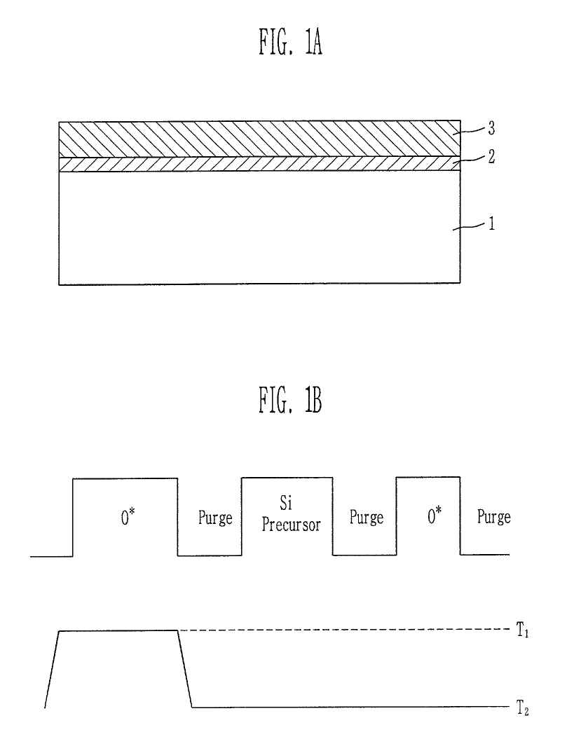

FIG. 1a is a cross-sectional view of a semiconductor device for explaining a method of forming an oxide film made of a thermal oxide film and a deposition oxide film, and FIG. 1b is a process flow for explaining FIG. 1a.

Referring now to FIG. 1a, a thermal oxide film 2 is grown on a silicon substrate 1. Then, a deposition oxide film 3 is formed on the thermal oxide film 2. First, the thermal oxide film 2 of a given thickness is grown on the surface of the silicon substrate 1 by supplying oxygen radicals or ozone into the chamber of a given temperature (T₁).

In case that the thermal oxide film is grown using ozone or oxygen radical, the growth temperature is lower than the case of using oxygen molecules. However, the thermal oxide film is generally grown at the temperature of more than 500° C. If the growth temperature of oxide is low, the temperature of the substrate is lowered. For this temperature control, a rapid thermal process (RTP) is employed so that the temperature of the substrate can be controlled by means of a radiant heat of a lamp.

After the temperature (T₂) inside the chamber is lowered, a purge process is performed if the temperature is stabilized. Thereafter, after silicon organic source or SiH₄ is supplied into the chamber, a purge process is performed. A reaction gas is supplied into the chamber to form the silicon deposition oxide film 3 on the thermal oxide film 2.

As above, a deposition process of one cycle that consists of a silicon precursor injection step, a first purge step, an ozone or oxygen injection step and a second purge step is repeatedly performed to form an oxide film of a given thickness.

The silicon organic source used as the silicon (Si) precursor may include Si(OC₂H₅)₄ (TEOS), Si(N(CH₃)₂)₄ (TDMAS), Si(N(C₂H₅)₂)₄, Si(CH₃)₄, Si(C₂H₅)₄, etc. Oxygen radical (O*) dissolved by plasma, ozone (O₃) obtained using ultraviolet, etc. are used as a reaction gas. As this oxygen radical or ozone has a good reactivity, it helps an oxide film having a good characteristic to be grown at low temperature.

In case of growing an oxide film having a good stack density using a chemical vapor deposition (CVD) method, TEOS or TDMAS is generally used as a source. In this case, the oxide film (SiO₂) is deposited at the rate of several Å per minutes at the temperature of 300-500° C. However, the present invention employs an atomic layer deposition equipment. Thus, the amount of oxide deposited in one cycle is self-limited but the thickness of 10-30 Å per minutes can be deposited due to a high deposition speed. This deposition speed has a close relation with the size of the chamber. In order to grow the thermal oxide film of 70 Å, about 30 minutes of time is required. Thus, there is a significant difference in the growth rate.

That is, the thermal oxide film has better interface characteristic and film quality than the deposition oxide film but is slower in the growth speed than the deposition oxide film. Therefore, the present invention grows the thermal oxide film 2 at the interface of the silicon substrate 1 and then forms the deposition oxide film 3 on the thermal oxide film 2 in-situ to obtain an oxide film having good interface and deposition speed characteristics.

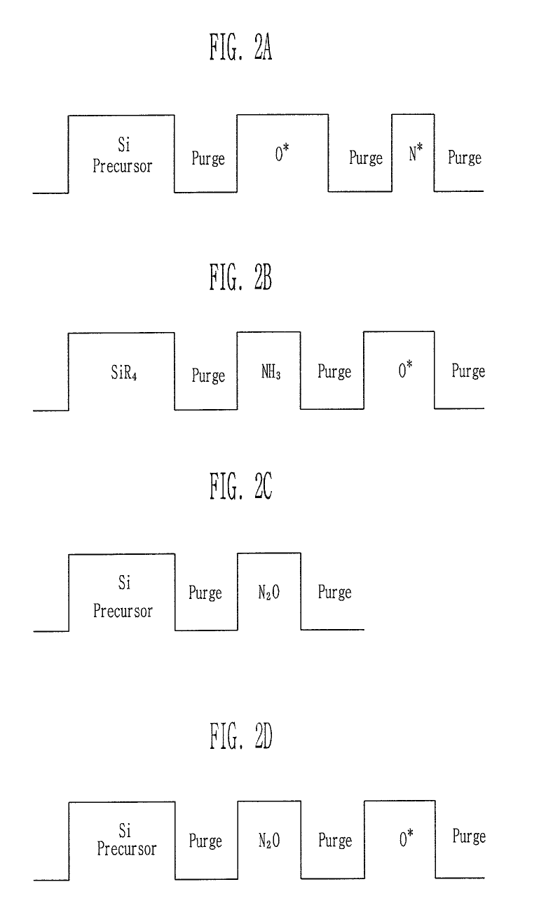

FIGS. 2a through 2d are process flows for explaining a method of forming a silicon oxynitride film according to one embodiment of the present invention.

Referring now to FIG. 2a, there is shown a process of depositing a silicon oxynitride film that consists of a silicon precursor injection step, a first purge step, an oxygen radical injection step, a second purge step and a nitrogen radical injection step. The injection time of oxygen radical and nitrogen radical is controlled to adjust the composition ratio of oxygen and nitrogen.

FIG. 2b shows a process of forming a silicon oxynitride (Si-O-N) film that consists of a SiR₄ (R is legand, i.e., CH₃, C₂H₅, NCH₃, OC₂H₅, etc.) injection step, a purge step, an ammonium injection step and an oxygen radical injection step.

FIG. 2c is a process of forming a silicon nitride film that consists of a silicon precursor injection step, a first purge step, a N₂O injection step and a second purge step. In this case, it is difficult to independently control the composition ratio of oxygen and nitrogen. Therefore, as shown in FIG. 2d, the first purge step is performed after a silicon precursor is injected and the second purge is performed after N₂O is injected. In addition, after oxygen radical is injected, a third purge step is performed to form a silicon nitride film.

As above, the composition of nitrogen and oxygen can be independently controlled by additionally using oxygen radical.

Meanwhile, as the process in FIG. 2c using only the silicon precursor and N₂O as a reaction gas can reduce the number of the process step, it is advantageous to apply the process of FIG. 2c in view of the productivity if a desired composition is possible by some degree.

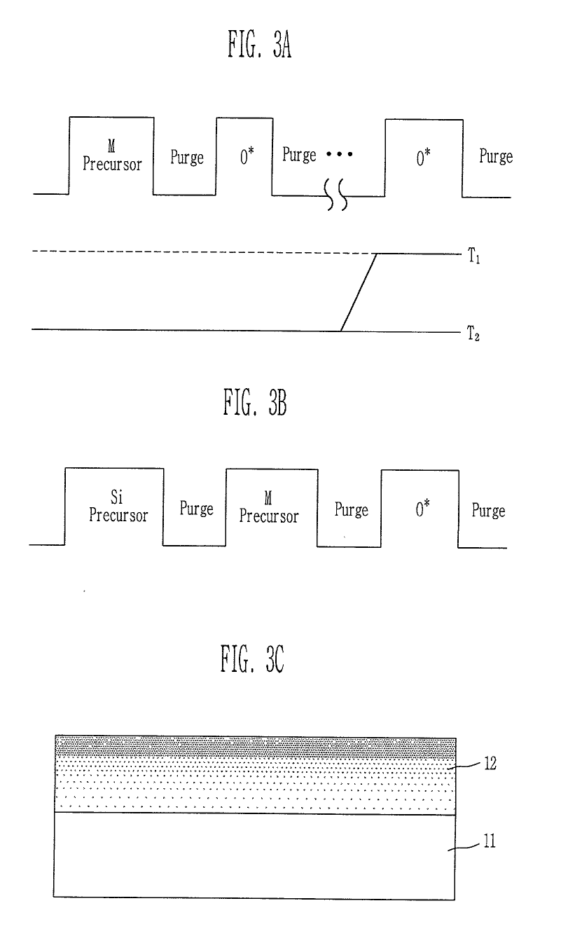

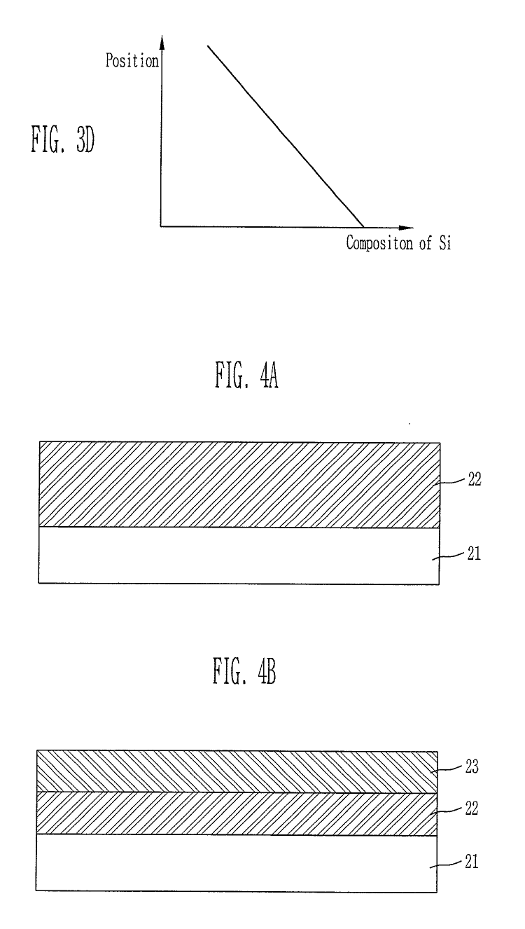

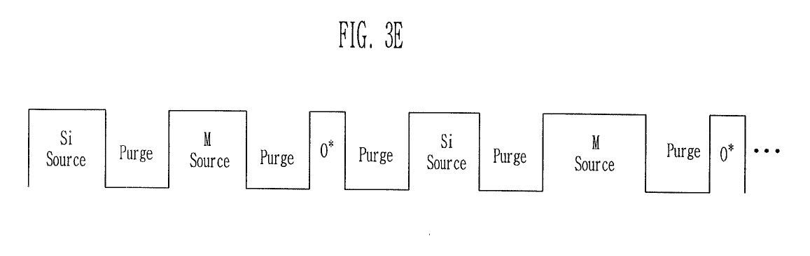

FIGS. 3a through 3d are process flows for explaining a method of forming a metal oxide film having a high dielectric constant according to one embodiment of the present invention.

Metals having a high dielectric constant include elements of Ta, Ti, Al, Y, Zr, Hf and a lanthanum group. The metal precursor may include alkoxide series of M(OR)ₓ, amine series of M(NR₂)ₓ and alkyle series of MRₓ (R is an alkyl radical such as CH₃, C₂H₅, C₃H₇, C₄H₉, etc.) as an organic substance. The reaction gas may include oxygen radical or ozone. In the existing atomic layer deposition (ALD) method, the metal oxide is deposited using a MClₓ precursor and H₂O as a reaction gas. In the present invention, however, oxide is deposited using reaction of an organic substance precursor with oxygen radical. If the oxide is deposited using an organic substance at low temperature, a porous film having a low density can be formed and an impurity such as carbon may remain. Specially, if this deposited oxide is used as a gate oxide film, degradation of oxygen is caused. Therefore, if the thin film is grown and the thin film is then maintained at an oxygen radical atmosphere with increased temperature, the content of carbon is significantly lowered and the density of the thin film is increased. Thus, as shown in FIG. 3a, a deposition process consisting of a metal precursor injection step, a first purge step, an oxygen radical injection step and a second purge step at a low temperature (T₂) is performed. Then, an annealing process is performed under oxygen or oxygen radical atmosphere at a high temperature with the temperature (T₁) raised.

Recently, it was reported that silicate of SiₓHf₁₋ₓO_{y}, SiₓZr₁₋ₓO_{y}, etc. in which a metal oxide of a high dielectric constant such as Hf or Zr is added to silicon is maintained at an amorphous state even at a high temperature. There is shown a process of adding silicon to form the metal oxide in FIG. 3b.

FIG. 3b shows a process of forming the metal oxide that consists of a silicon precursor injection step, a first purge step, a metal (M) precursor injection step, a second purge step, an oxygen radical injection step and a third purge step. At this time, it is very important to control the composition ratio of silicon and metal (M). The composition ratio of metal and silicon could be controlled by adjusting the injection time of silicon and metal. If the composition of silicon and metal is uniform, a constant process time can be maintained as the process period is repeated.

If the amount of silicon is increased, the dielectric constant is usually lowered but the crystallization temperature is increased. Therefore, if the composition within the interface and the thin film is controlled, a further optimum condition can be easily obtained. It would be thus effective to control the growth of the thin film by means of the ALD method than chemical vapor deposition method.

For example, as shown in FIG. 3e, if the injection time of silicon is reduced, the injection time of metal is increased as the process is proceeded, the content of silicon within the metal oxide 12 is reduced as it is far from the interface with the silicon substrate 11, as shown in the graph of FIG. 3d.

FIG. 3c shows the metal oxide 12 formed on the silicon substrate 11, which shows that the content of silicon within the metal oxide 12 is reduced as it is far from the interface with the silicon substrate 11.

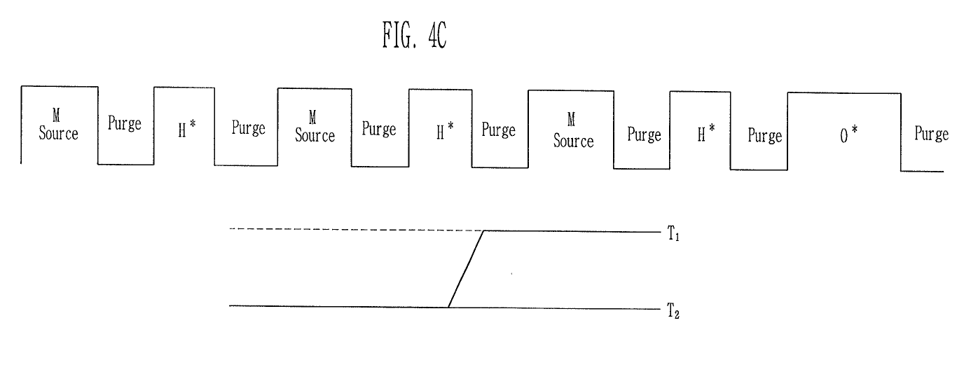

FIG. 4a and FIG. 4b are cross-sectional views of the device for explaining a method of forming a metal thermal oxide film according to another embodiment of the present invention, and FIG. 4c is a process flow for explaining FIG. 4a and FIG. 4b.

FIG. 4a is a cross-sectional view of the metal thermal oxide film in which a metal 22 is deposited on a silicon substrate 21 using a metal organic source and FIG. 4b is a cross-sectional view of the metal thermal oxide film in which the metal 22 is oxidized using a hydrogen radical as a reaction gas to form a metal oxide film 23.

As shown in FIG. 4c, after a metal is deposited at a low temperature (T₂), as shown in FIG. 4a, the temperature is raised so that the metal can be exposed to oxygen radical of a high temperature (T₁), thus forming the metal oxide film 23.

As shown in FIG. 4c, a process consisting of a metal injection step, a first purge step, a hydrogen radical injection step and a second purge step, at a low temperature (T₂), are repeatedly performed to deposit a metal of a desired thickness. Then, the temperature is raised so that the metal can be exposed to the oxygen radical, thus forming the metal oxide film 23.

The metal thermal oxide film formed thus has a good and stable film quality. These processes are possible in a metal on which the thermal oxide film can be formed.

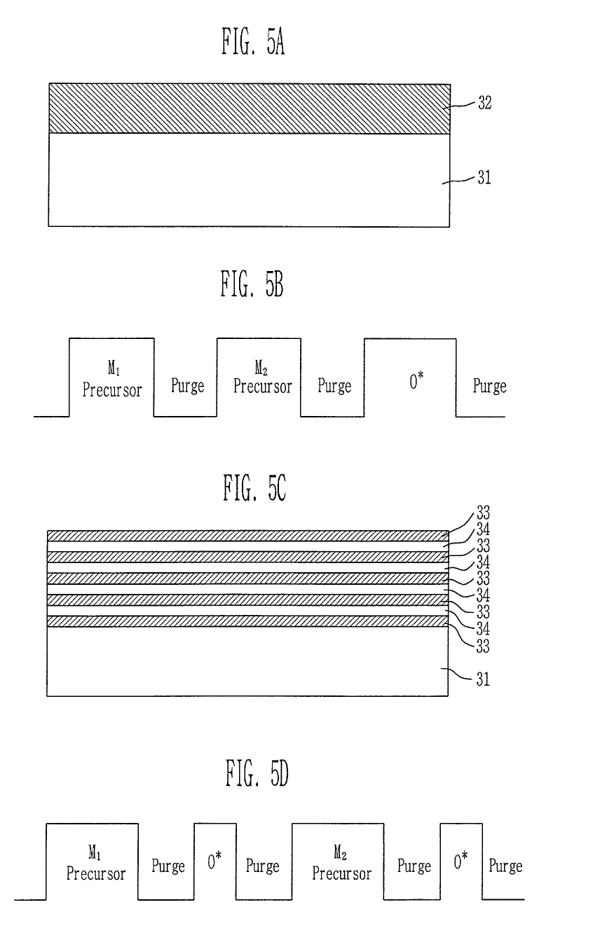

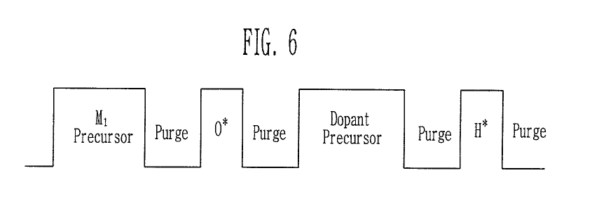

FIGS. 5a and FIG. 5c are cross-sectional views for explaining a method of forming a metal oxide film made of an oxidized mixture of a metal (M₁) and another metal (M₂), and FIG. 5b and FIG. 5d are process flows for explaining FIG. 5a and FIG. 5c.

FIG. 5a is a cross-sectional view of the metal oxide film 32 formed on a silicon substrate 31, which is made of an oxidized metal compound. As shown in FIG. 5b, a first metal (M₁) precursor injection step, a first purge step, a second metal (M₂) precursor injection step and a second purge step are sequentially performed to form the metal oxide film 32 on the silicon substrate 31.

Referring to FIG. 5c, the first metal oxide film 33 made of the metal (M₁) and the second metal oxide film 34 made of the metal (M₂) are alternately stacked on the silicon substrate 31. As shown in FIG. 5d, a first metal (M₁) precursor injection step, a first purge step, an oxygen radical injection step, a second purge step, a second metal (M₂) precursor injection step and a third purge step are sequentially performed to alternately stack the first metal oxide film 33 and the second metal oxide film 34 on the silicon substrate 31.

In other words, FIG. 5a and FIG. 5b present a technology of oxidizing two metal compounds at once to form a metal oxide film while FIG. 5c and FIG. 5d present a technology of alternately stacking and oxidizing different two metal oxides to form a metal oxide film.

As above, the shape of oxide can be varied depending on the supply time of the precursor and radical. Generally, the leakage current characteristic is degraded as the gate oxide film has a lot of interfaces. It is advantageous that an oxide film of a compound shape is used rather than a structure in which oxides are stacked in view of the characteristic of the device.

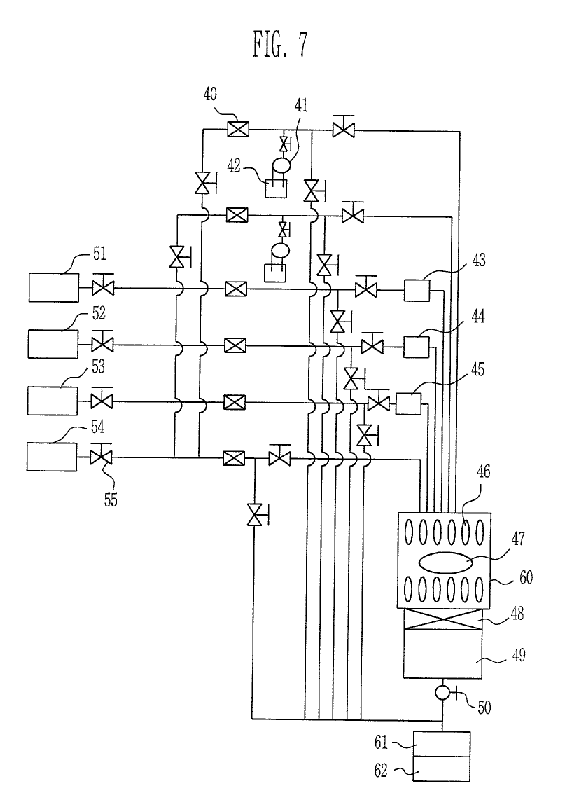

FIG. 6 is a process flow for explaining a metal oxide film for which doping is performed. The process consists of a metal precursor injection step, a first purge step, an oxygen radical injection step, a second purge step, a dopant precursor injection step, a third purge step, a hydrogen radical injection step and a fourth purge step.

In case of forming a metal oxide film having a good interface characteristic by doping 4-group materials to 3-group or 5-group metal oxides or forming an oxide film by adding silicon or aluminum to TaOₓ, a dopant precursor is used in order to improve the characteristic, as above. At this time, the dopant reduces the hydrogen radical.

FIG. 7 is a construction of a deposition apparatus used to deposit oxide on a semiconductor substrate using an atomic layer deposition method.

The deposition equipment used in the present invention cannot only independently control the supply of gas but also can be applied both to the ALD method or the CVD method.

An organic source can be stored at a container 42 and the organic source vaporized depending on the operation of the metering valve 41 is supplied into the chamber 60 for controlling the flow amount of vapor, as it usually exists in an liquid state. Though there are shown two liquid organic source containers in FIG. 7, the number of the liquid organic source containers is not limited two. A number of containers can be used for containing a lot of source.

Carrier gases for carrying the liquid source of a vapor state may include argon (Ar), etc. This carrier gas is stored at a gas container 54 and is supplied into the chamber 60 depending on the operation of the open and shut valve 55 and the mass flow controller 40. Hydrogen (H) used as a reaction gas is stored at the gas container 51 and is supplied into the plasma generator 43 depending on the operation of the open and shut valve 55 and the mass flow controller 40. Also, the hydrogen (H) is dissolved by plasma in a hydrogen radical state and is then supplied into the chamber 60. Oxygen (O) used as the reaction gas is stored at the gas container 52 and is supplied into the plasma generator 44 or an ultraviolet generator (not shown) depending on the operation of the open and shut valve 55 and the mass flow controller 40. Also, oxygen (O) is dissolved by plasma in an oxygen radical state and is then supplied into the chamber 60 where it causes an oxidization reaction. Nitrogen (N) is stored at the gas container 534 and is supplied into the plasma generator 45 depending on the operation of the open and shut valve 55 and the mass flow controller 40. Also, nitrogen (N) is dissolved in a radical state by plasma and is then supplied into the chamber 60. A wafer 47 is located at the rear of the chamber 60 and a plurality of lamps 46 for rapid thermal process are installed around the wafer 47.

Also, a turbo molecule pump 49 for making an internal atmosphere in an ultra high vacuum state is connected to the chamber 60 via the gate valve 48. The turbo molecule pump 49 is connected to the boost pump 61 and the dry pump 62 through the shield valve 59.

Meanwhile, the tube passages, to which the organic source and individual gases are supplied, are connected to the boost pump 61 and the dry pump 62 through the valves.

As can be understood from the above description, according to the present invention, a thermal oxidization process and a deposition process are sequentially performed to form an oxide film having good interface characteristic and deposition speed. Also, an oxide film, an oxynitride film and a metal oxide film are deposited using an atomic layer deposition (ALD) method, by controlling the pulse construction and the supply time of source and radical in order for them to have a good interface characteristic. Therefore, the present invention has outstanding effects that it can easily control the content, the composition ratio and doping concentration of a material and can obtain an oxide film having good leakage current and interface characteristics.

The present invention has been described with reference to a particular embodiment in connection with a particular application. Those having ordinary skill in the art and access to the teachings of the present invention will recognize additional modifications and applications within the scope thereof.

It is therefore intended by the appended claims to cover any and all such applications, modifications, and embodiments within the scope of the present invention.

What is claimed are:

1. A method of forming an insulating film in a semiconductor device comprising the steps of:
providing a silicon substrate on which an under layer is formed; and
alternately performing a first process of injecting a silicon source and a second process of injecting an oxidization reaction gas to form an oxide film on said under layer,
wherein said oxidization reaction gas employs oxygen radical or ozone.

2. The method of forming an insulating film in a semiconductor device according to claim 1, wherein said silicon source is any one of a silicon organic precursor and SiH₄.

3. The method of forming an insulating film in a semiconductor device according to claim 2, wherein said silicon organic precursor includes alkoxide series of Si(OR)₄, amine series of Si(NR₂)₄ and alkyle series of SiR₄, where R is CH₃, C₂H₅, C₃H₇ or C₄H₉.

4. The method of forming an insulating film in a semiconductor device according to claim 1, wherein said oxide film is formed by using any one of an atomic layer deposition (ALD) apparatus.

5. The method of forming an insulating film in a semiconductor device according to claim 1, further including the step of forming a thermal oxide film on said under layer by means of a thermal oxidization process using oxygen radical or ozone, before said first process is performed.

6. The method of forming an insulating film in a semiconductor device according to claim 5, wherein said steps of forming said thermal oxide film and said oxide film are performed in-situ method.

7. A method of forming an insulating film in a semiconductor device comprising the step of forming a silicon oxynitride film using a silicon organic precursor, an oxygen precursor and a nitrogen precursor,
wherein said oxygen precursor employs an oxygen radical, and said nitrogen precursor employs one of a nitrogen radical, ammonium and N₂O.

8. The method of forming an insulating film in a semiconductor device according to claim 7, wherein said silicon organic precursor includes alkyle series of SiR₄, where R is CH₃, C₂H₅, NCH₃ or OC₂H₅.

9. The method of forming an insulating film in a semiconductor device according to claim 7, wherein said silicon oxynitride film is formed by sequentially performing the silicon organic precursor injection process, the oxygen radical injection process and the nitrogen radical injection process.

10. The method of forming an insulating film in a semiconductor device according to claim 7, wherein said silicon oxynitride film is formed by sequentially performing the silicon organic precursor injection process, the ammonium injection process and the oxygen radical injection process.

11. The method of forming an insulating film in a semiconductor device according to claim 7, wherein said silicon oxynitride film is formed by sequentially performing the silicon organic precursor injection process, the N₂O injection process and the oxygen radical injection process.

12. A method of forming an insulating film in a semiconductor device comprising the step of alternately performing a metal precursor injection process and an oxidization reaction gas injection process to form a metal oxide film on a silicon substrate,
wherein said oxidization reaction gas employs oxygen radical or ozone.

13. The method of forming an insulating film in a semiconductor device according to claim 12, farther including the step of performing a rapid thermal process under oxygen radical atmosphere after said metal oxide film is formed.

14. The method of forming an insulating film in a semiconductor device according to claim 12, wherein the further including the step of performing the silicon precursor injection process before the metal precursor injection process.

15. The method of forming an insulating film in a semiconductor device according to claim 14, wherein in said silicon precursor injection process and said metal precursor injection process, the composition of silicon and metal is controlled by the process time.

16. The method of forming an insulating film in a semiconductor device according to claim 15, wherein said silicon precursor injection process and said metal precursor injection process are repeatedly performed, and wherein the composition of silicon and metal is adjusted by gradually reducing the time to inject the silicon precursor and gradually increasing the time to inject the metal precursor.

17. The method of forming an insulating film in a semiconductor device according to claim 12, wherein said metal precursor injection process is performed in two steps where different metal precursors are used in each step.

18. The method of forming an insulating film in a semiconductor device according to claim 12, wherein said metal precursor injection process is performed in two steps, where different metal precursors are used in each step, and wherein after each step, the oxidization reaction gas injection process is performed to form different types of metal oxide films in a multi-layer structure.

19. A method of forming an insulating film in a semiconductor device comprising the steps of:
alternately performing a metal precursor injection process and a hydrogen radical injection process; and
performing an annealing process under oxygen radical or ozone atmosphere to form a metal thermal oxide film.

20. A method of forming an insulating film in a semiconductor device comprising the step of:
alternately performing a metal precursor injection process, an oxygen radical injection process, a dopant precursor injection process and a hydrogen radical injection process to form a metal oxide film.

21. The method of forming an insulating film in a semiconductor device according to claim 12, 19 or 20, wherein said metal precursor includes alkoxide series of M(OR)ₓ, amine series of M(NR₂)ₓ and alkyle series of MRₓ, where R is CH₃, C₂H₅, C₃H₇ or C₄H₉.

22. The method of forming an insulating film in a semiconductor device according to claim 12 or 20, wherein said metal oxide film is any one of oxides of lanthanum group metals such as TiO₂, Ta₂O₅, Al₂O₃, ZrO₂, HfO₂, Y₂O₃ and La₂O₃, Gd₂O₃ and Pr₂O₃ to which said dopant precursor is injected.

23. The method of forming an insulating film in a semiconductor device according to claim 19, wherein said metal thermal oxide film is any one of oxides of lanthanum group metals such as TiO₂, Ta₂O₅, Al₂O₃, ZrO₂, HfO₂, Y₂O₃ and La₂O₃, Gd₂O₃ and Pr₂O₃ to which said dopant precursor is injected.

24. The method of forming an insulating film in a semiconductor device according to claim 19, wherein said silicon oxynitride film is formed by an atomic layer deposition (ALD) method.

25. The method of forming an insulating film in a semiconductor device according to claim 12 or 20, wherein said metal oxide film is formed by an atomic layer deposition (ALD) method.

26. The method of forming an insulating film in a semiconductor device according to claim 19, wherein said metal thermal oxide film is formed by an atomic layer deposition (ALD) method.
